(19) United States
(12) Patent Application Publication
(10) Pub. No.: US 2021/0199716 A1
(43) Pub. Date: Jul. 1, 2021

(54) TESTING DEVICE AND TESTING METHOD

(71) Applicant: KABUSHIKI KAISHA TOKAI RIKA DENKI SEISAKUSHO, Aichi (JP)

(72) Inventor: Sunao NAGAI, Aichi (JP)

(73) Assignee: KABUSHIKI KAISHA TOKAI RIKA DENKI SEISAKUSHO, Aichi (JP)

(21) Appl. No.: 17/123,612

(22) Filed: Dec. 16, 2020

(30) Foreign Application Priority Data
Dec. 27, 2019 (JP) 2019-238156

(51) Int. Cl. G01R 31/3163

(52) U.S. Cl. CPC G01R 31/3163

(57) ABSTRACT

When testing a reset circuit, a first register outputs a set signal to an OR circuit of the reset circuit so that a logic circuit is not reset even if an input voltage is low. Further, when testing the reset circuit, the first register turns off a regulator circuit by outputting a set signal from a second register to the regulator circuit and supplying the input voltage to the reset circuit from an external device via a voltage application terminal. Subsequently, the input voltage supplied from the voltage application terminal is varied and an output signal of a comparator output from a signal output circuit through an external terminal is checked to test whether the reset circuit is actuated normally.

### BACKGROUND

### 1. Field

The following description relates to a testing device and a method for testing an analog circuit.

### 2. Description of Related Art

A typical semiconductor integrated circuit includes a reset circuit that stops signal outputs for a specified period of time from when power is supplied (refer to Japanese Laid-Open Patent Publication No. 2015-127710). When, for example, DC voltage is applied to the semiconductor integrated circuit as a power supply voltage, signals output from the semiconductor integrated circuit may be unstable for a specified period of time until the DC voltage becomes stable. The reset circuit stops the output of signals from the semiconductor integrated circuit during this period to ensure stable actuation of the semiconductor integrated circuit.

The inventors have conducted detailed studies and found that when a reset circuit is arranged in a semiconductor integrated circuit, the semiconductor integrated circuit typically requires an input terminal for supplying the reset circuit with a signal that indicates when testing is initiated and an output terminal for outputs from the reset circuit. Thus, the device cannot be reduced in size and simplified in structure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one aspect, a testing device includes an analog circuit, an overriding unit, and a switch output. The analog circuit is configured to compare an input voltage and a threshold value with a comparator. Based on a control signal corresponding to the comparison result, the analog circuit is configured to actuate a logic circuit in a first actuation state when the input voltage is less than the threshold value and actuate the logic circuit in a second actuation state when the input voltage is greater than or equal to the threshold value. When testing the analog circuit, the overriding unit is configured to output a set signal to the analog circuit from an element arranged in advance in the logic circuit so that the logic circuit is shifted to the second actuation state even if the input voltage is less than the threshold value. The switch output is arranged in the logic circuit and switched to a state for monitoring an output signal of the comparator and outputting the output signal of the comparator to a device outside the logic circuit when testing the analog circuit. When testing the analog circuit, the testing device varies the input voltage supplied to the comparator and checks the output signal of the comparator from an output of the switch output to determine whether the analog circuit is actuated normally.

In another aspect, a testing method includes comparing, by an analog circuit, an input voltage and a threshold value with a comparator. Based on a control signal corresponding to the comparison result, a logic circuit is actuated in a first actuation state when the input voltage is less than the threshold value and the logic circuit is actuated in a second actuation state when the input voltage becomes greater than or equal to the threshold value. The method further includes shifting the logic circuit to the second actuation state even if the input voltage is less than the threshold value by outputting a set signal to the analog circuit from an element arranged in advance in the logic circuit when testing the analog circuit. The method further includes outputting an output signal of the comparator via a switch output arranged in the logic circuit to a device outside the logic circuit by switching the switch output to a state for monitoring the output signal of the comparator when testing the analog circuit. The method further includes testing whether the analog circuit is actuated normally by varying the input voltage supplied to the comparator and checking the output signal of the comparator from an output of the switch output when testing the analog circuit.

Other features and aspects will be apparent from the following detailed description, the drawings, and the claims.

### BRIEF DESCRIPTION OF THE DRAWINGS

FIG. 1 is a diagram showing the configuration of a testing device in accordance with one embodiment.

FIG. 2 is a diagram showing normal operation of the testing device.

FIG. 3 is a timing diagram illustrating the actuation flow of the testing device.

FIG. 4 is a diagram showing a state in which the testing device is conducting a test.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

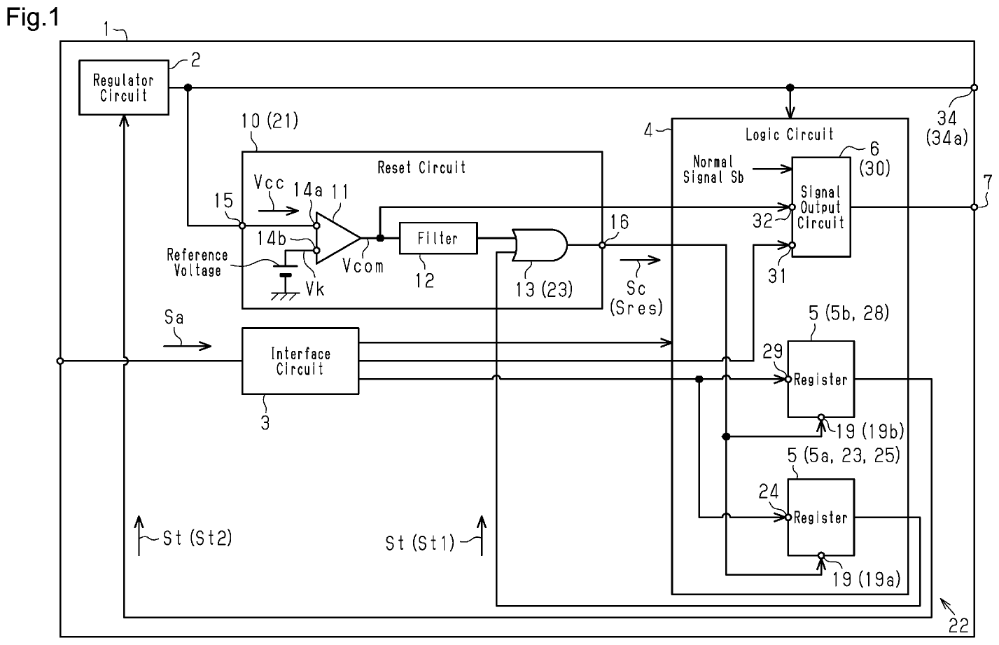

One embodiment of a testing device and a testing method will now be described with reference to FIGS. 1 to 4.

As shown in FIG. 1, a semiconductor integrated circuit 1 includes a regulator circuit 2, an interface circuit 3, and a logic circuit 4. The regulator circuit 2 converts a power supply voltage to voltage of a predetermined value. The interface circuit 3 receives a communication signal Sa from an external device. The logic circuit 4 is actuated based on the voltage received from the regulator circuit 2. The logic circuit 4 includes multiple registers 5 (in present example, first register 5a and second register 5b) and a signal output circuit 6. The signal output circuit 6 outputs various signals and data processed in the semiconductor integrated circuit 1 to an external device. The signal output circuit 6 is connected to an external terminal 7 of the semiconductor integrated circuit 1.

During a normal operation, the semiconductor integrated circuit 1 receives various signals and data from an external device as the communication signal Sa with the interface circuit 3. The semiconductor integrated circuit 1 holds the signals and data, which are received from the interface circuit 3, in the registers 5 of the logic circuit 4 to perform various actions. Further, when the semiconductor integrated circuit 1 outputs a normal signal Sb, which is the processing result of the input signals and data, during a normal operation, the semiconductor integrated circuit 1 outputs the normal signal Sb from the signal output circuit 6 through the external terminal 7 to another device or apparatus.

The semiconductor integrated circuit 1 includes a reset circuit 10, or a power-on reset circuit, that activates the logic circuit 4 after the power supply becomes stable. The reset circuit 10 includes a comparator 11, a filter 12, and an OR circuit 13. The comparator 11 includes two input terminals 14a and 14b. The input terminal 14a is connected via a connection terminal 15 of the reset circuit 10 to the regulator circuit 2. The input terminal 14b is supplied with a reference voltage. The comparator 11 compares an input voltage Vcc supplied from the regulator circuit 2 with a threshold value Vk corresponding to the reference voltage and outputs a comparator output signal Vcom as a comparison result to the filter 12. The comparator output signal Vcom is output as a control signal Sc (reset signal Sres in present example) via the filter 12 and the OR circuit 13 from an output terminal 16 of the reset circuit 10 to the logic circuit 4.

Each register 5 includes a reset input terminal 19 that receives the reset signal Sres. In the present example, the reset input terminal 19 of the first register 5a is denoted as “19a”, and the reset input terminal 19 of the second register 5b is denoted as “19b”. The register 5, when activated at a time point in which the reset input terminal 19 receives the reset signal Sres, the register 5 starts various processes such as the holding of various data received from the interface circuit 3.

When the input voltage Vcc is less than the threshold value Vk, that is, when the reset signal Sres is not received, the logic circuit 4 is in an “OFF” state, or a first actuation state. When the input voltage Vcc is greater than or equal to the threshold value Vk, that is, when the reset signal Sres is received, the logic circuit 4 is in an “ON” state, or a second actuation state. In this manner, the logic circuit 4 is activated at a time point at which the reset signal Sres is received from the reset circuit 10. Then, the logic circuit 4 starts processing various signals and data received via the interface circuit 3 from an external device and outputs a normal signal Sb as the processing result from the external terminal 7 to another device or apparatus.

The semiconductor integrated circuit 1 includes a testing device 22 that tests the reset circuit 10 to check whether the reset circuit 10 is functioning normally. The reset circuit 10 is as an analog circuit 21 that serves as a tested subject. The testing device 22 of the present example uses and controls the logic circuit 4, which is arranged in advance in the semiconductor integrated circuit 1, to test and check whether the reset circuit 10 is functioning normally.

The testing device 22 includes an overriding unit 23 that maintains the logic circuit 4 in an ON state so that the logic circuit 4 will not be turned off when testing the reset circuit 10. In the present example, the overriding unit 23 is includes the first register 5a and the OR circuit 13. The first register 5a includes a connection terminal 24 that is connected to the interface circuit 3. When the connection terminal 24 receives a testing request as a communication signal Sa from the interface circuit 3, the first register 5a outputs a set signal St (first set signal St in present example) for testing the OR circuit 13 of the reset circuit 10.

When the OR circuit 13 receives the set signal St from the first register 5a, the reset circuit 10 maintains a state in which the output terminal 16 outputs the reset signal Sres regardless of the state of the output signal Vcom of the comparator 11. In this manner, when testing the reset circuit 10, the overriding unit 23 is configured to output the set signal St from an element 25 arranged in advance in the logic circuit 4 (first register 5a in present example) to the reset circuit 10 so that the logic circuit 4 is turned on even when the input voltage Vcc is less than the threshold value Vk.

The testing device 22 includes a regulator deactivator 28 that deactivates the regulator circuit 2 when testing the reset circuit 10. In the present example, the regulator deactivator 28 is the second register 5b arranged in the logic circuit 4. The second register 5b includes a connection terminal 29 that is connected to the interface circuit 3. When the connection terminal 29 receives a testing request as the communication signal Sa from the interface circuit 3, the second register 5b outputs the set signal St (second set signal St2 in present example) for testing the regulator circuit 2. The regulator circuit 2 is switched on and off based on the set signal St received from the second register 5b.

The testing device 22 includes a switch output 30 that outputs the output signal Vcom of the comparator 11 instead of the normal signal Sb to a device outside the logic circuit 4 when testing the reset circuit 10. In the present example, the switch output 30 is the signal output circuit 6 arranged in the logic circuit 4. The signal output circuit 6 includes a connection terminal 31 that is connected to the interface circuit 3.

Further, the signal output circuit 6 includes a connection terminal 32 that receives the output signal Vcom of the comparator 11. When the connection terminal 31 receives a testing request as the communication signal Sa from the interface circuit 3, the signal output circuit 6 is switched from a state in which the signal output circuit 6 outputs a normal signal Sb to an external device to a state in which the signal output circuit 6 outputs the output signal Vcom of the comparator 11 to an external device. In other words, when testing the reset circuit 10, the signal output circuit 6 outputs the output signal Vcom of the comparator 11 from the external terminal 7. In this manner, when testing the reset circuit 10, the switch output 30 switches to a state for monitoring the output signal Vcom of the comparator 11 and outputs the output signal Vcom of the comparator 11 to a device outside the logic circuit 4.

The testing device 22 includes a connection port 34 that outputs the output of the regulator circuit 2 (converted voltage Vcc) to any circuit outside the semiconductor integrated circuit 1. In the present example, when testing the reset circuit 10, the connection port 34 serves as a terminal (hereinafter, voltage application terminal 34a) that allows voltage from an external device to be applied to the semiconductor integrated circuit 1. The voltage application terminal 34a is connected to the input terminal 14a of the comparator 11, which is supplied with the input voltage Vcc. When testing the reset circuit 10, if the regulator circuit 2 is deactivated, instead of the regulator circuit 2, the testing device 22 supplies the comparator 11 with the input voltage Vcc from the voltage application terminal 34a and varies the input voltage Vcc to test the reset circuit 10.

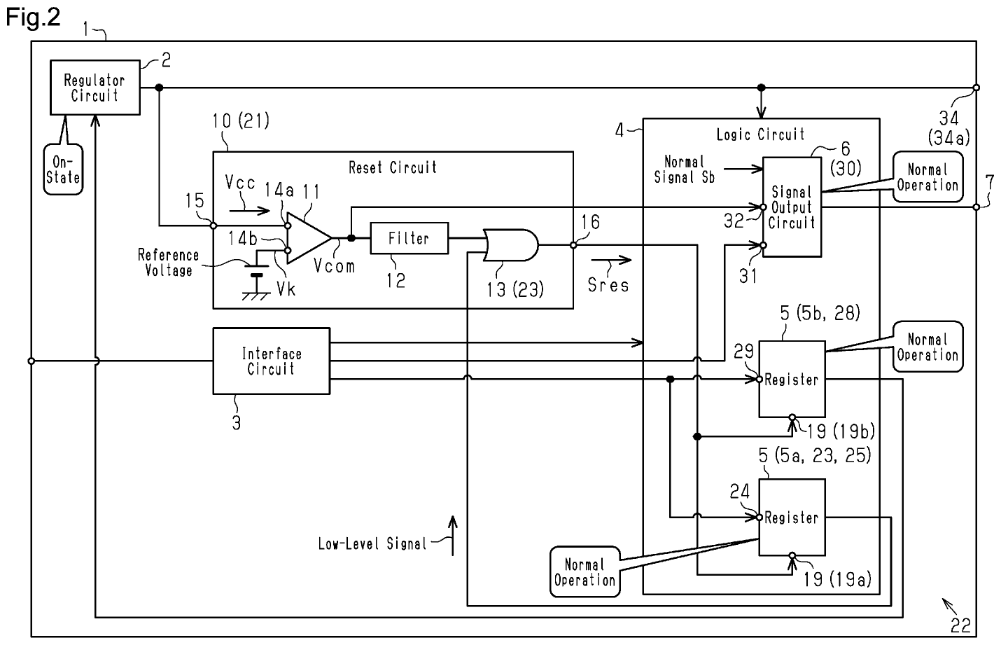

The operation of the testing device 22 in accordance with the present embodiment will now be described with reference to FIGS. 2 to 4.

Normal Operation

As shown in FIG. 2, during a normal operation, the first register 5a does not receive a testing request via the interface circuit 3 from an external device. Thus, the first register 5a is actuated in a normal manner and does not output the set signal St (first set signal St1) to the OR circuit 13. Accordingly, a low-level signal is input to one input of the OR circuit 13.

During a normal operation, the second register 5b does not receive a testing request via the interface circuit 3 from an external device. Thus, the second register 5b is actuated in a normal manner and does not output the set signal St (second set signal St2) to the regulator circuit 2. Accordingly, the regulator circuit 2 is in an ON state and supplies voltage to the input terminal 14a of the reset circuit 10 and to the logic circuit 4.

During a normal operation, the signal output circuit 6 does not receive a testing request via the interface circuit 3 from an external device and is thus actuated in a normal manner. In this case, the signal output circuit 6 outputs the normal signal Sb (various signals and data) from the external terminal 7 based on actuation of the logic circuit 4. Further, the voltage of the regulator circuit 2 is supplied from the voltage application terminal 34a to any circuit outside the semiconductor integrated circuit 1.

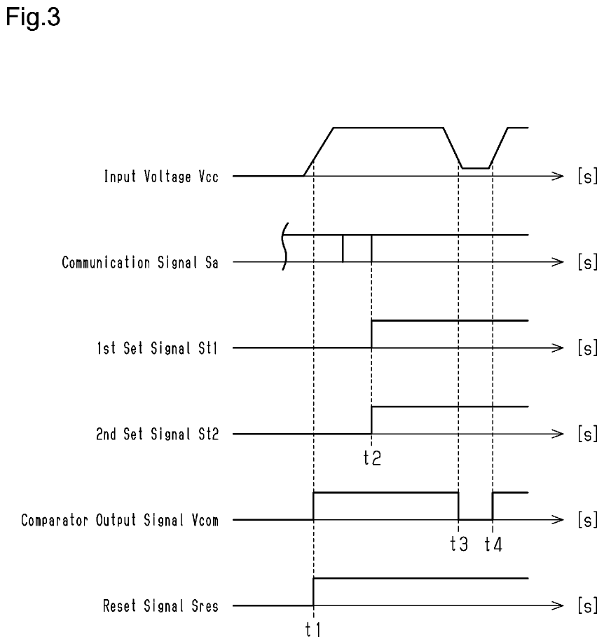

As illustrated in FIG. 3, when activating the semiconductor integrated circuit 1, the regulator circuit 2, which is in an ON state, increases and supplies the input voltage Vcc to the input terminal 14a of the comparator 11. When power is first supplied, the input voltage Vcc is lower than the threshold value Vk, which is set by the reference voltage. Thus, the comparator 11 outputs a low-level output signal Vcom via the filter 12 to the OR circuit 13. In this case, both inputs of the OR circuit 13 have a low-level. Thus, the reset circuit 10 does not output the reset signal Sres to the logic circuit 4, and the logic circuit 4 remains turned off.

When the input voltage Vcc becomes greater than or equal to the threshold value Vk (time t1), the comparator 11 outputs a high-level output signal Vcom via the filter 12 to the OR circuit 13. Accordingly, one input of the OR circuit 13 has a high level. Thus, the reset circuit 10 outputs the reset signal Sres to the logic circuit 4. When the first register 5a and the second register 5b are reset by the reset signal Sres, the logic circuit 4 is activated to start various processes. In this manner, the semiconductor integrated circuit 1 is actuated in a normal manner.

Testing of Reset Circuit 10

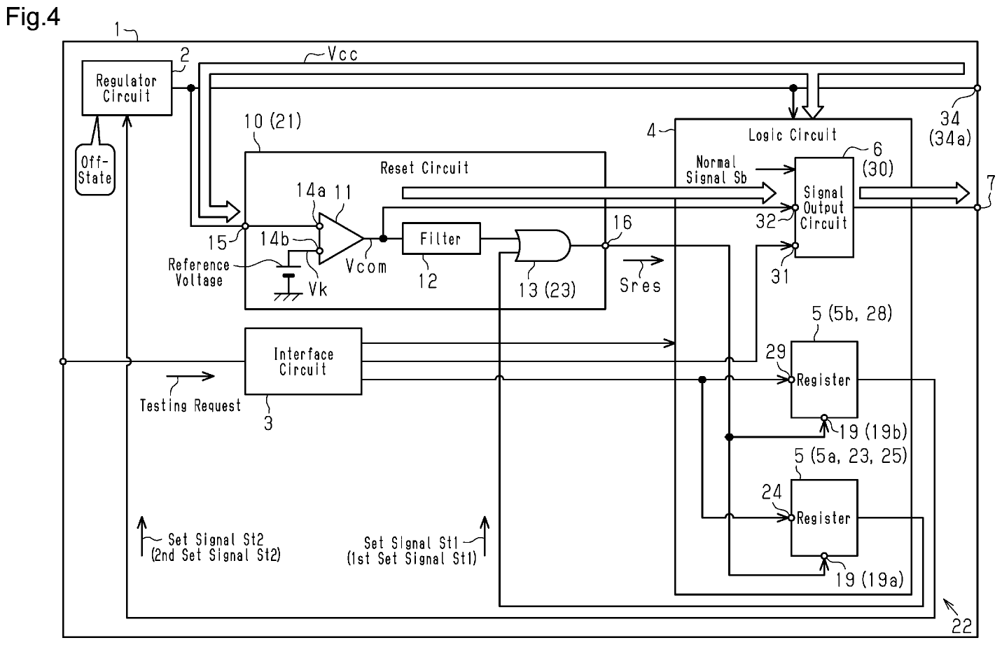

As shown in FIG. 4, when testing the reset circuit 10, a testing request is input to the interface circuit 3 that is used during a normal operation. The testing request is input to the first register 5a, the second register 5b, and the signal output circuit 6. When the testing request is received from the interface circuit 3, instead of testing the reset circuit 10 in a normal manner, the first register 5a, the second register 5b, and the signal output circuit 6 actuate the reset circuit 10 to conduct a test. In other words, the logic circuit 4 is shifted to a test mode.

As illustrated in FIG. 3, when the connection terminal 24 receives a testing request, the first register 5a outputs the set signal St (first set signal St1) to the OR circuit 13 (time t2). In the present example, the first set signal St is a high-level signal. Accordingly, a high-level signal is input to one input of the OR circuit 13. Thus, the reset circuit 10 constantly outputs the reset signal Sres. In this manner, the first register 5a and the second register 5b are activated and the logic circuit 4 remains turned on and is not turned off.

Further, when the connection terminal 29 receives a testing request, the second register 5b outputs a set signal St (second set signal St2) to the regulator circuit 2 (time t2). When the regulator circuit 2 receives the second set signal St2 from the second register 5b, the regulator circuit 2 is switched from an ON state to an OFF state. In other words, the reset circuit 10 is not supplied with voltage from the regulator circuit 2. Further, the voltage of the regulator circuit 2 is not supplied from the voltage application terminal 34a to any circuit outside the semiconductor integrated circuit 1. In the present example, the voltage applied from the voltage application terminal 34a to the logic circuit 4 and to the reset circuit 10 is the same before and after the regulator circuit 2 is turned off.

In the test mode, the voltage applied from the voltage application terminal 34a to the reset circuit 10 is varied. Then, when the reset circuit 10 is switched on and off, that is, when the output signal Vcom of the comparator 11 is switched between a high level and a low level, the voltage of the voltage application terminal 34a is checked to determine whether a reset function is normal. In the present example, the normality of the reset function is checked when the semiconductor integrated circuit 1 is switched from on to off and when the semiconductor integrated circuit 1 is switched from off to on.

In the present example, when the semiconductor integrated circuit 1 is ON, the input voltage Vcc applied to the voltage application terminal 34a is gradually decreased. Subsequently, when the output signal Vcom of the comparator 11 is switched from on to off (time t3), the value of the input voltage Vcc applied to the voltage application terminal 34a is checked. In this case, if the voltage is included within an allowable range, the reset function is determined to be normal for when the semiconductor integrated circuit 1 is switched from on to off. In this manner, the semiconductor integrated circuit 1 is checked to determine the normality of the reset function when switched from on to off.

After the reset function is checked for when the semiconductor integrated circuit 1 is switched from on to of, the semiconductor integrated circuit 1 is checked to determine the normality of the reset function for when switched from off to on. In this case, the input voltage Vcc applied to the voltage application terminal 34a is gradually increased. Subsequently, when the output signal Vcom of the comparator 11 is switched from off to on (time t4), the value of the input voltage Vcc applied to the voltage application terminal 34a is checked. In this case, if the voltage is included within an allowable range, the reset function is determined to be normal for when the semiconductor integrated circuit 1 is switched from off to on. In this manner, the semiconductor integrated circuit 1 is checked to determine the normality of the reset function when switched from off to on.

The testing device 22 of the above-described embodiment has the following advantages.

(1) The testing device 22 includes the overriding unit 23 configured to output the set signal St from the element 25, which is arranged in advance in the logic circuit 4, to the analog circuit 21 when testing the analog circuit 21 to shift the logic circuit 4 to the second actuation state even if the input voltage Vcc is less than the threshold value Vk. The testing device 22 includes the switch output 30 in the logic circuit 4 to switch to a state for monitoring the output signal Vcom of the comparator 11 when testing the analog circuit 21 and output the output signal Vcom of the comparator 11 to a device outside the logic circuit 4. Further, when testing the analog circuit 21, the input voltage Vcc is varied and supplied to the comparator 11. Subsequently, the output signal Vcom of the comparator 11 is checked based on the output of the switch output 30 to determine whether the analog circuit 21 is actuated in a normal manner.

The present example is configured so that the logic circuit 4 arranged in the analog circuit 21 is used to test whether the analog circuit 21 can be actuated in a normal manner. This eliminates the need for the arrangement of another member to test whether the analog circuit 21 can be actuated. Thus, the configuration of the testing device 22 is simplified.

(2) The logic circuit 4 is used for testing so that the logic circuit 4 can be shifted or set to, for example, a complicated test mode. Further, for example, if a dedicated testing terminal were to be used to input signals, a test mode may be selected inadvertently. However, the present example avoids such a problem.

(3) The logic circuit 4 used for testing reduces the area occupied by chips of elements related to the semiconductor integrated circuit 1 or the reset circuit 10.

(4) The analog circuit 21 is the reset circuit 10 that resets the logic circuit 4 after a predetermined time elapses from when power is supplied. The reset circuit 10, which compares the input voltage Vcc and the threshold value Vk with the comparator 11, turns off the logic circuit 4 by not outputting the reset signal Sres to the logic circuit 4 when the input voltage Vcc is less than the threshold value Vk. Further, the reset circuit 10 turns on the logic circuit 4 by outputting the reset signal Sres to the logic circuit 4 when the input voltage Vcc is greater than or equal to the threshold value Vk. In this case, the reset circuit 10 can be tested for normality without arranging another terminal for testing in the reset circuit 10 or in the semiconductor integrated circuit 1. This simplifies the configuration of the testing device 22 in the reset circuit 10.

(5) When a testing request is received from the interface circuit 3, which receives signals during a normal operation, at least one of the overriding unit 23 and the switch output 30 tests the reset circuit 10. In this case, the reset circuit 10 is tested using the interface circuit 3. Thus, there is no need for another test terminal.

(6) The testing device 22 includes the regulator deactivator 28 in the logic circuit 4 that deactivates the regulator circuit 2 when testing the reset circuit 10 by outputting the set signal St to the regulator circuit 2, which supplies the input voltage Vcc to the comparator 11. Further, when testing the reset circuit 10, the testing device 22 supplies the comparator 11 with the input voltage Vcc from an external device instead of the regulator circuit 2 and varies the input voltage Vcc from the external device to test the reset circuit 10. In this case, the reset circuit 10 is tested to determine whether it can be actuated in a normal manner by varying the input voltage Vcc applied from an external device to the reset circuit 10.

(7) When a testing request is received from the interface circuit 3, which is used for inputting signals during a normal operation, the regulator deactivator 28 outputs the set signal St to the regulator circuit 2 to deactivate the regulator circuit 2. In this case, the regulator circuit 2 is deactivated using the interface circuit 3. Thus, there is no need for another test terminal.

The present embodiment may be modified as follows. The present embodiment and the following modifications can be combined as long as the combined modifications remain technically consistent with each other.

Overriding Unit 23

The overriding unit 23 does not have to be formed by the first register 5a and the OR circuit 13. For example, the overriding unit 23 may be formed by only the first register 5a as long as a member corresponding to the OR circuit is arranged in advance in the reset circuit 10.

The set signal St (first set signal St1) output from the first register 5a does not have to be a high-level signal. For example, the set signal St may have a low level and be inverted from high to low when switching between a normal operation and a test mode. Further, the set signal St may be a data signal including specified information.

The overriding unit 23 may be any member configured to keep the logic circuit 4 turned on when testing the reset circuit 10.

The element 25 of the logic circuit 4 is not limited to the register 5 (first register 5a), and various devices other than the register arranged in advance in the logic circuit 4 may be used.

Switch Output 30

The switch output 30 is not limited to the signal output circuit 6 that is configured to output the normal signal Sb and switch the outputs. For example, the switch output 30 may be a switching element arranged in the path of the output signal Vcom of the comparator 11. In this case, when the switching element is turned on, the signal output circuit 6 outputs the output signal Vcom of the comparator 11 to an external device.

The switch output 30 may only be a member configured to supply the output of the comparator 11 to an external device when conducting a test.

Testing of Reset Circuit 10

From a state in which the semiconductor integrated circuit 1 is deactivated, the ret circuit 10 may be tested immediately after power is supplied.

When testing the reset circuit 10, the testing does not have to be performed by deactivating the regulator circuit 2 and supplying the input voltage Vcc from an external device to the reset circuit 10. For example, the reset circuit 10 may be tested by varying the input voltage Vcc input from the regulator circuit 2 to the comparator 11. In this case, the voltage application terminal 34a, which applies the input voltage Vcc from an external device, may be omitted.

The testing request does not have to be received from the interface circuit 3. For example, a testing request may be input to a dedicated terminal arranged in the semiconductor integrated circuit 1.

Analog Circuit 21

The analog circuit 21 is not limited to the reset circuit 10 and may be any circuit that needs to be tested.

The analog circuit 21 is not limited to the reset circuit 10 and may be any type of circuit.

First Actuation State and Second Actuation State

The first actuation state is not limited to a state in which the logic circuit 4 is turned off and may be changed to any state.

The second actuation state is not limited to a state in which the logic circuit 4 is turned on and may be changed to any state.

The first actuation state and the second actuation state only need to be opposite actuation states.

Control Signal Sc

The control signal Sc is not limited to the reset signal Sres and may be any signal that is output in accordance with the type of the analog circuit 21.

The control signal Sc may be any signal configured to control actuation of the logic circuit 4.

Others

The normal operation may be any operation other than testing.

The semiconductor integrated circuit 1 may be an in-vehicle circuit or may be used for other devices or apparatus.

Technical concepts that can be understood from the above embodiment and the modified examples will now be described.

(a) A testing device for testing a reset circuit, the reset circuit comparing an input voltage and a threshold value with a comparator to turn a logic circuit off by not inputting a reset signal to the logic circuit while the input voltage is less than the threshold value and turn the logic circuit on by outputting the reset signal to the logic circuit when the input voltage becomes greater than or equal to the threshold value, the testing device including an overriding unit configured to turn the logic circuit on when testing the reset circuit even if the input voltage is less than the threshold value by outputting a set signal from an element arranged in advance in the logic circuit, and a switch output arranged in the logic circuit and switched to a state for monitoring an output signal of the comparator to output the output signal of the comparator to a device outside the logic circuit when testing the reset circuit, wherein the testing device varies the input voltage input to the comparator and checks the output signal of the comparator from an output of the switch output to test whether the reset circuit is actuated normally.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A testing device, comprising:
an analog circuit configured to compare an input voltage and a threshold value with a comparator, based on a control signal corresponding to the comparison result, actuate a logic circuit in a first actuation state when the input voltage is less than the threshold value, and actuate the logic circuit in a second actuation state when the input voltage is greater than or equal to the threshold value;
an overriding unit configured to output a set signal to the analog circuit from an element arranged in advance in the logic circuit when testing the analog circuit so that the logic circuit is shifted to the second actuation state even if the input voltage is less than the threshold value; and
a switch output arranged in the logic circuit and switched to a state for monitoring an output signal of the comparator and outputting the output signal of the comparator to a device outside the logic circuit when testing the analog circuit,
wherein when testing the analog circuit, the testing device varies the input voltage supplied to the comparator and checks the output signal of the comparator from an output of the switch output to determine whether the analog circuit is actuated normally.

2. The testing device according to claim 1, wherein
the analog circuit is a reset circuit that compares the input voltage and the threshold value with the comparator, turns the logic circuit off by not outputting a reset signal to the logic circuit while the input voltage is less than the threshold value, and turns the logic circuit on by outputting the reset signal to the logic circuit when the input voltage becomes greater than or equal to the threshold value,
the control signal is a reset signal,
the first actuation state is a state in which the logic circuit is turned of, and
the second actuation state is a state in which the logic circuit is turned on.

3. The testing device according to claim 2, wherein at least one of the overriding unit and the switch output tests the reset circuit when receiving a testing request via an interface circuit that is used to input a signal during a normal operation.

4. The testing device according to claim 2, further comprising:
a regulator deactivator arranged in the logic circuit to deactivate a regulator circuit that supplies the input voltage to the comparator when testing the reset circuit by outputting the set signal to the regulator circuit,
wherein when testing the reset circuit, the testing device supplies the input voltage from an external device instead of the regulator circuit to the comparator and varies the input voltage from the external device to test the reset circuit.

5. The testing device according to claim 4, wherein when a testing request is received via an interface circuit that is used when inputting a signal during a normal operation, the regulator deactivator outputs the set signal to the regulator circuit to deactivate the regulator circuit.

6. A method for testing, comprising:
comparing, by an analog circuit, an input voltage and a threshold value with a comparator, based on a control signal corresponding to the comparison result, actuating a logic circuit in a first actuation state when the input voltage is less than the threshold value, and actuating the logic circuit in a second actuation state when the input voltage becomes greater than or equal to the threshold value,
shifting the logic circuit to the second actuation state even if the input voltage is less than the threshold value by outputting a set signal to the analog circuit from an element arranged in advance in the logic circuit when testing the analog circuit;
outputting an output signal of the comparator via a switch output arranged in the logic circuit to a device outside the logic circuit by switching the switch output to a state for monitoring the output signal of the comparator when testing the analog circuit; and
testing whether the analog circuit is actuated normally by varying the input voltage supplied to the comparator and checking the output signal of the comparator from an output of the switch output when testing the analog circuit.

7. The method according to claim 6, wherein
the analog circuit is a reset circuit that compares the input voltage and the threshold value with the comparator, turns the logic circuit off by not outputting a reset signal to the logic circuit while the input voltage is less than the threshold value during a normal operation, and turns the logic circuit on by outputting the reset signal to the logic circuit when the input voltage becomes greater than or equal to the threshold value,
the control signal is a reset signal,
the first actuation state is a state in which the logic circuit is turned of, and
the second actuation state is a state in which the logic circuit is turned on.

8. The method according to claim 7, further comprising starting testing of the analog circuit when the logic circuit receives a testing request via an interface circuit that is used to input a signal during a normal operation.

9. The method according to claim 7 further comprising:
deactivating a regulator, which supplies the input voltage to the comparator, with a regulator deactivator arranged in the logic circuit by outputting the set signal when testing the analog circuit,
wherein the testing whether the analog circuit is actuated normally includes testing the analog circuit by supplying the input voltage from an external device instead of the regulator circuit to the comparator and varying the input voltage from the external device when testing the analog circuit.

10. The method according to claim 9, further comprising deactivating the regulator circuit by outputting the set signal to the regulator circuit when a testing request is received via an interface circuit that is used for inputting a signal during a normal operation.
